(19) United States
(12) Patent Application Publication
(10) Pub. No.: US 2025/0366231 A1
(43) Pub. Date: Nov. 27, 2025

(54) EPITAXIAL STRUCTURES IN IMAGE SENSORS

(71) Applicant: Taiwan Semiconductor Manufacturing Company, Ltd., Hsinchu (TW)

(72) Inventor: Shih-Yu LIAO, Hsinchu City (TW)

(73) Assignee: Taiwan Semiconductor Manufacturing Company, Ltd., Hsinchu (TW)

(21) Appl. No.: 19/292,799

(22) Filed: Aug. 6, 2025

Related U.S. Application Data
(63) Continuation of application No. 18/646,444, filed on Apr. 25, 2024.
(60) Provisional application No. 63/533,261, filed on Aug. 17, 2023.

(51) Int. Cl. H10F 39/00; G01S 7/481; H10F 39/12; H10F 39/18

(52) U.S. Cl. CPC H10F 39/8033; H10F 39/011; H10F 39/1843; H10F 39/199; H10F 39/807; H10F 39/811; G01S 7/4816

(57) ABSTRACT

A semiconductor device with an image sensor and a method of fabricating the same are disclosed. The semiconductor device includes a substrate, a pixel region with a pixel structure, an isolation region with an isolation structure disposed adjacent to the pixel region, and a contact pad region with a pad structure disposed adjacent to the isolation region. The pixel structure includes an epitaxial structure, which includes an embedded portion with a stepped structure disposed in the substrate and a protruding portion extending above a top surface of the substrate. The pixel structure further includes a capping layer disposed on the protruding portion.

### CROSS-REFERENCE TO RELATED APPLICATIONS

This application is a continuation of U.S. patent application Ser. No. 18/646,444, titled “Epitaxial Structures in Image Sensors,” filed Apr. 25, 2024, which claims the benefit of U.S. Provisional Patent Application No. 63/533,261 titled “Quantum Effect Material of Semiconductor Photonic Device and Method for Forming the Same,” filed Aug. 17, 2023, each of which is incorporated by reference herein in its entirety.

### BACKGROUND

Image sensors are used to sense incoming visible or non-visible radiation, such as visible light and infrared light. Complementary metal-oxide-semiconductor (CMOS) image sensors (CIS) and charge-coupled device (CCD) sensors are used in various applications, such as digital still cameras, mobile phones, tablets, and goggles. These image sensors utilize an array of pixel structures that absorb (e.g., sense) an incoming radiation and convert it into electrical signals. An example of an image sensor is a back-side illuminated (BSI) image sensor, which detects radiation from a “back-side” of a substrate of the BSI image sensor.

### BRIEF DESCRIPTION OF THE DRAWINGS

Aspects of this disclosure are best understood from the following detailed description when read with the accompanying figures.

FIG. 1A illustrates a cross-sectional view of a semiconductor device with a BSI image sensor, in accordance with some embodiments.

FIGS. 1B and 1C illustrate different cross-sectional views of pixel structures of a BSI image sensor, in accordance with some embodiments.

FIG. 1D illustrates a cross-sectional view of another semiconductor device with a BSI image sensor, in accordance with some embodiments.

FIG. 1E illustrate cross-sectional views of another pixel structure of a BSI image sensor, in accordance with some embodiments.

FIG. 2 is a flow diagram of a method for fabricating a semiconductor device with a BSI image sensor, in accordance with some embodiments.

FIGS. 3-20 illustrate cross-sectional views of a semiconductor device with a BSI image sensor at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, -2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

A BSI image sensor (e.g., time-of-flight sensor) includes a pixel region (also referred to as a “radiation-sensing region”) with an array of pixel structures formed on a substrate (e.g., a semiconductor substrate). The pixel structures are configured to receive a radiation (e.g., infra-red radiation) reflected from an object and convert photons from the received radiation to an electrical signal. The electrical signal is subsequently distributed to processing components attached to the BSI image sensor. For this reason, the pixel structures overlie a multi-level metallization layer configured to distribute the electrical signal generated in the pixel structures to appropriate processing components.

The multi-level metallization layer is coupled to a first surface (also referred to as a “front-side surface”) of the substrate. The pixel structures are formed on the front-side surface of the substrate and the radiation is received by the pixel structures through a second surface (also referred to as a “back-side surface”) of the substrate that is opposite to the front-side surface of the substrate. Each of the pixel structures can include an epitaxial structure disposed in the substrate, a silicon (Si)-based capping layer disposed on the epitaxial structure, and doped regions disposed in the epitaxial structure and the Si-based capping layer. The Si-based capping layers can passivate the epitaxial structures and provide silicon atoms for the formation of silicide structures on the doped regions.

One of the challenges of forming BSI image sensors is controlling the top surface profiles of the epitaxial structures during the formation of the epitaxial structures and/or during the formation of the Si-based capping layers and/or other overlying layers. Non-uniformity in the top surface profiles of the epitaxial structures can be introduced during a high temperature reflow process performed on the epitaxial structures and/or during high temperature (e.g., temperature greater than 500° C.) processing of overlying layers, such as the Si-based capping layers. The high temperature can cause the material of the epitaxial structures to become ductile and laterally flow over the edges of the trenches in which the epitaxial structures are formed and over the dielectric layer surrounding the epitaxial structures and/or the Si-based capping layers. Such non-uniformity in the top surfaces of the epitaxial structures can lead to the formation of air gaps between the epitaxial structures and the Si-based capping layers and/or between the epitaxial structures and the sidewalls of the trenches. These air gaps can introduce processing chemicals (e.g., etching solutions or cleaning solutions) into the epitaxial structures during the processing of the overlying layers and damage the epitaxial structures.

To overcome the above-mentioned challenges, the present disclosure provides example structures and methods for improving the surface uniformity of the epitaxial structures in a BSI image sensor and as a result, improving the interfaces between the epitaxial structures and the Si-based capping layers and/or between the epitaxial structures and the sidewalls of the trenches. In some embodiments, the epitaxial structures can be formed in trenches with sidewalls having stepped profiles or having curved profiles. Such structures of the trenches can prevent or minimize the materials of the epitaxial structures from laterally expanding over the edges of the trenches and over the dielectric layer during the high temperatures processes.

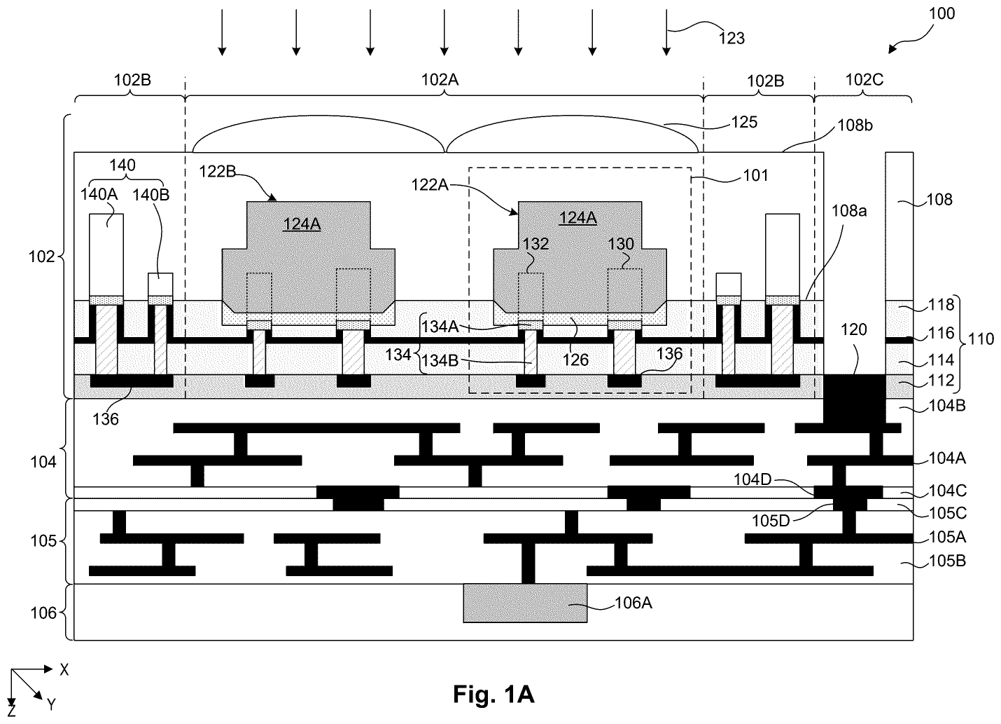

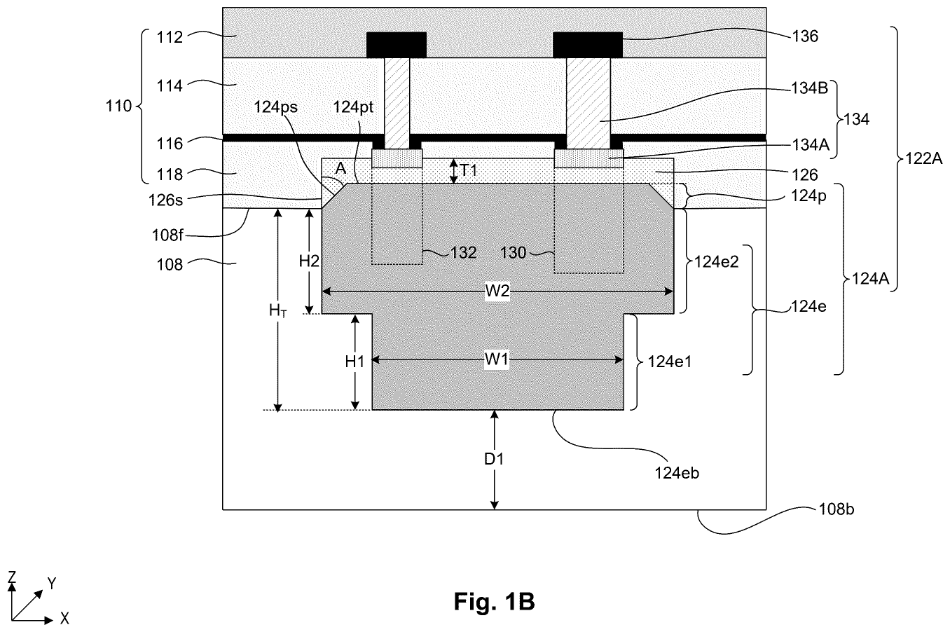

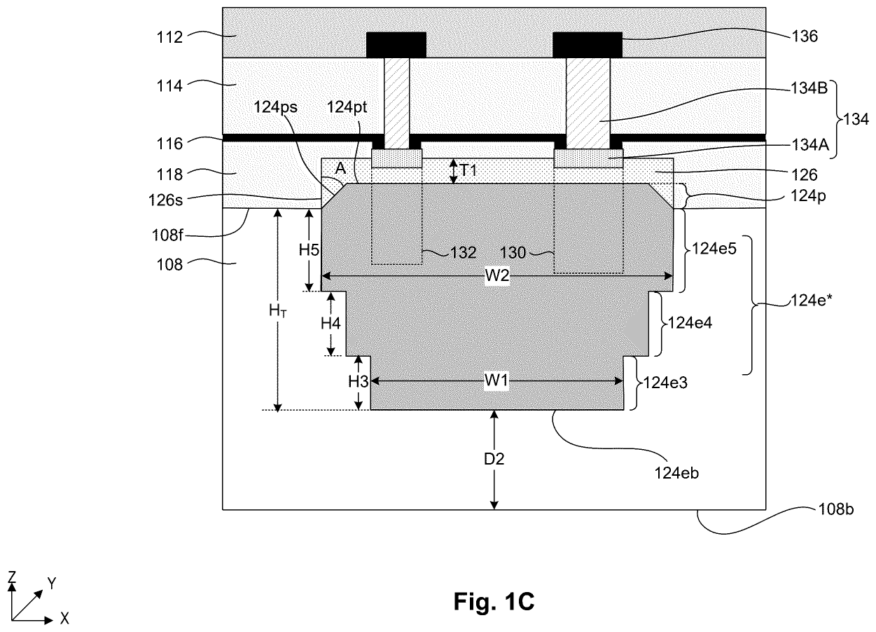

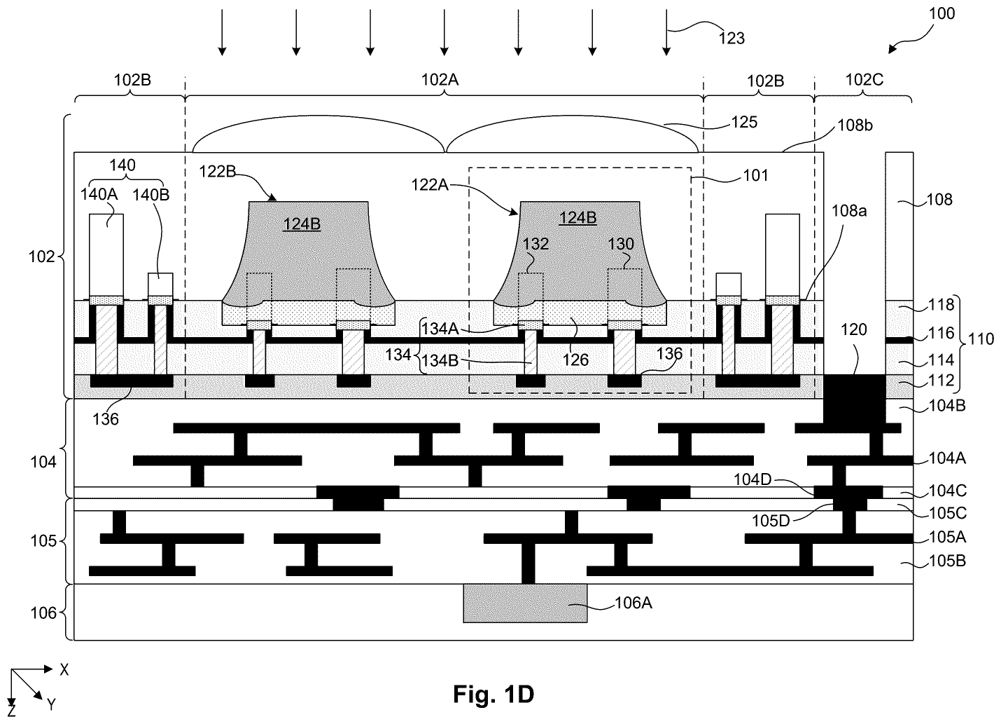

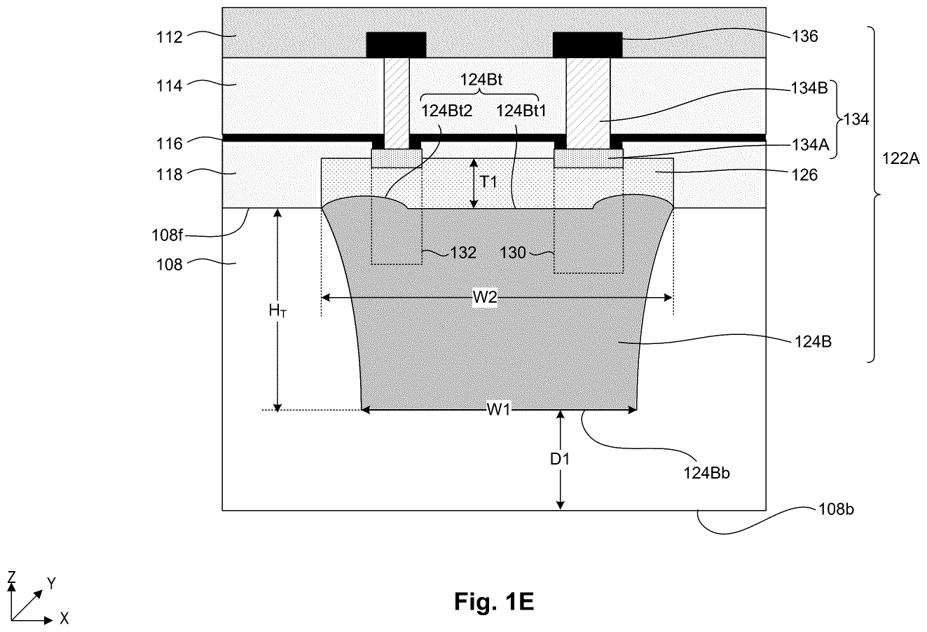

FIG. 1A illustrates a cross-sectional view of a semiconductor device 100, according to some embodiments. FIGS. 1B and 1C illustrate enlarged different cross-sectional views of a region 101 of FIG. 1A, according to various embodiments. The discussion of elements in FIGS. 1A, 1B, and 1C with the same annotations applies to each other, unless mentioned otherwise.

In some embodiments, semiconductor device 100 can include (i) a BSI image sensor 102, (ii) a first multi-level metallization layer 104, (ii) a second multi-level metallization layer 105, and (iv) an application specific integrated circuit (ASIC) 106.

Referring to FIG. 1A, BSI image sensor 102 can be disposed on and electrically connected to first multi-level metallization layer 104. First multi-level metallization layer 104 can be disposed on second multi-level metallization layer 105, which can be disposed on and electrically connected to ASIC 106. First multi-level metallization layer 104 can include a multi-level interconnect structure 104A embedded in an inter-metal dielectric (IMD) layer 104B, which is disposed on a bonding layer 104C with metal lines 104D. Similarly, second multi-level metallization layer 105 can include a multi-level interconnect structure 105A embedded in an IMD layer 105B and a bonding layer 105C with metal lines 105D disposed on IMD layer 105B. Bonding layers 104C and 105C can be bonded to each other by a suitable bonding method, such as direct bonding, eutectic bonding, hybrid bonding, and optical fusion bonding, and can be electrically connected to each other through metal lines 104D and 105D. As a result, BSI image sensor 102 can be electrically connected to ASIC 106 through first and second multi-level metallization layers 104 and 105. ASIC 106 can include active devices 106A (e.g., transistor structures) to form logic and memory circuits. In some embodiments, active devices 106A can be configured to process electrical signals received from BSI image sensor 102.

In some embodiments, BSI image sensor 102 can include (i) a substrate 108 with a front-side surface 108a and a back-side surface 108b, (ii) a stack of layers 110 disposed on front-side surface 108a, and (iii) micro-lens 125 disposed on back-side surface 108b. In some embodiments, substrate 108 can include a monocrystalline silicon substrate. In some embodiments, substrate 108 can include a semiconductor material, such as Si, Ge, SiGe, silicon carbide (SiC), indium phosphide (InP), gallium arsenide (GaAs), silicon arsenide (SiAs), gallium phosphide (GaP), indium phosphide (InP), silicon germanium carbide (SiGeC), germanium stannum (GeSn), silicon germanium stannum (SiGeSn), gallium arsenic phosphide (GaAsP), gallium indium phosphide (GaInP), gallium indium arsenide (GaInAs), gallium indium arsenic phosphide (GaInAsP), and any other suitable semiconductor material. In some embodiments, substrate 108 can include a silicon-on-insulator (SOI) structure or a germanium-on-insulator (GOI) structure.

Referring to FIGS. 1A and 1B, in some embodiments, stack of layers 110 can include (i) a passivation layer 112 disposed on first multi-level metallization layer 104, (ii) an interlayer dielectric (ILD) layer 114 disposed on passivation layer 112, (iii) an etch stop layer (ESL) 116 disposed on ILD layer 114, and (iv) a dielectric layer 118 disposed on ESL 116. In some embodiments, dielectric layer 118 can include a nitride layer, an oxide layer, an oxynitride layer, or a suitable dielectric material. In some embodiments, dielectric layer 118 can include an oxide of a material of substrate 108, such as silicon oxide (SiOₓ). In some embodiments, ESL 116 can include a nitride layer, an oxide layer, an oxynitride layer, a carbide layer, or a suitable dielectric material. In some embodiments, ESL 116 can include silicon nitride (SiNx), silicon oxide (SiOx), silicon oxynitride (SiON), silicon carbide (SiC), silicon carbonitride (SiCN), boron nitride (BN), silicon boron nitride (SiBN), silicon carbon boron nitride (SiCBN), or a combination thereof. In some embodiments, ILD layer 114 can include a low-k dielectric layer (e.g., a dielectric with a dielectric constant less than about 3.9), an ultra-low-k dielectric layer (e.g., a dielectric with a dielectric constant less than about 2.5), or an oxide layer (e.g., silicon oxide (SiOₓ)). In some embodiments, passivation layers 112 can include a nitride layer, an oxide layer, an oxynitride layer, a polymer layer (e.g., polyimide or polybenzoxazole), or a combination thereof.

Referring to FIG. 1A, in some embodiments, BSI image sensor 102 can further include (i) a pixel region 102A, (ii) isolation regions 102B, and (iii) a contact pad region 102C, according to some embodiments. In some embodiments, pixel region 102A can include an array of pixel structures 122A and 122B. Though an array of two pixel structures 122A and 122B are shown, BSI image sensor 102 can have any number of pixel structures arranged in a one-dimensional array or a two-dimensional array. Pixel structures 122A and 122B are configured to receive incident radiation beams 123 through micro-lens 125 on back-side surface 108b and convert radiation beams 123 to an electrical signal. The electrical signal is distributed by pad structure 120 and first and second multi-level metallization layers 104 and 105 to ASIC 106 and/or other external circuits. Pixel structures 122A and 122B can be electrically isolated from each other by dielectric layer 118 and can be protected by passivation layers 112, ILD layer 114, and ESL 116 during fabrication of BSI image sensor 102. In some embodiments, pixel structures 122A and 122B can be similar to each other in structure and composition. The discussion of pixel structure 122A applies to pixel 122B, unless mentioned otherwise.

Referring to FIGS. 1A and 1B, in some embodiments, pixel structure 122A can include (i) an epitaxial structure 124A disposed in substrate 108, (ii) a capping layer 126 disposed on epitaxial structure 124A, (iii) a p-type doped region 130 disposed in epitaxial structure 124A and capping layer 126, (iv) an n-type doped region 132 disposed in epitaxial structure 124A and capping layer 126, (v) contact structures 134 disposed on p- and n-type doped regions 130 and 132, and (vi) via structures 136 disposed on contact structures 134.

Epitaxial structure 124A can be formed on front-side surface 108a and can include quantum effect material, such as Si, silicon germanium (SiGe), and a group III-V element of the periodic table. In some embodiments, epitaxial structure 124A can include a group IV element that is different from a group IV element of substrate 108. In some embodiments, epitaxial structure 124A can include undoped Ge or SiGe.

In some embodiments, epitaxial structure 124A can include an embedded portion 124e and a protruding portion 124p. Embedded portion 124e can be disposed in substrate 108 and protruding portion 124p can extend above front-side surface 108f of substrate 108. In some embodiments, protruding portion 124p can have a substantially planar top surface 124pt and sloped sidewalls 124ps. The sloped sidewalls 124ps can be separated from dielectric layer 118 by a portion of capping layer 126 and can form angles A of about 5 degrees or less with vertical sidewalls 126s of capping layer 126. If angles A are greater than about 5 degrees, chemicals (e.g., cleaning solutions) used during the processing of epitaxial structure 124A and/or capping layer 126 can seep into the interfaces between embedded portion 124e and substrate 108 and damage epitaxial structure 124A. In some embodiments, sidewalls 124ps of protruding portion 124p can be substantially vertical (not shown) and can be in contact with dielectric layer 118.

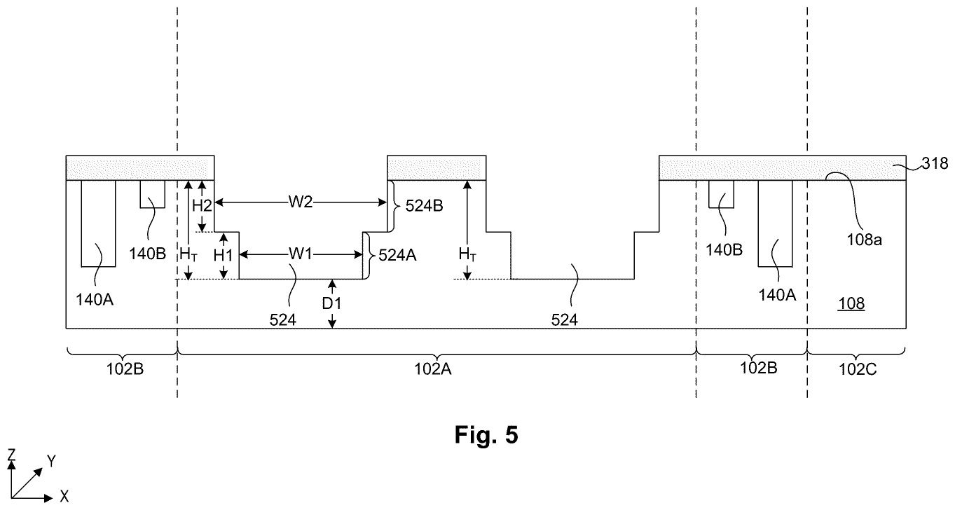

In some embodiments, embedded portion 124e of epitaxial structure 124A can have a stepped structure with sidewalls having stepped profiles. The stepped structure of embedded portion 124e can have a bottom portion 124e1 and a top portion 114e2, which is wider than bottom portion 124e1. In some embodiments, bottom portion 124e1 can have a width W1 equal to or greater than about 0.5 μm and top portion 124e2 can have a width W2 equal to or greater than about 1.2 times of width W1. In some embodiments, bottom portion 124e1 can have a height H1 of about 175 nm to about 200 nm and top portion 124e2 can have a height H2 of about 50 nm to about 100 nm. In some embodiments, height H2 can be equal to or greater than about 25% of total height H_{T} of embedded portion 124e and can be smaller than height H1. In some embodiments, embedded portion 124e can extend to height H_{T} of about 100 nm to about 200 nm below front-side surface 108f of substrate 108 and back-side surface 124eb of embedded portion 124e can be above back-side surface 108b of substrate 108 by a distance D1 of about 75 nm to about 125 nm. Within these ranges of widths W1 and W2, heights H1 and H2, and distance D1, the stepped structure of embedded portion 124e can prevent or minimize the material of epitaxial structure 124A from laterally expanding over the edges of trenches 524 (shown in FIG. 5) during high temperatures processes, as described in detail below.

Though the stepped structure of embedded portion 124e is shown in FIG. 1B to have a single step level, embedded portion 124e can have any number of step levels. For example, in some embodiments, epitaxial structure 124A can have an embedded portion 124e* with multiple step levels, as shown in FIG. 1C, instead of embedded portion 124e of FIG. 1B. In some embodiments, the stepped structure of embedded portion 124e* can have a bottommost portion 124e3, a middle portion 124e4, and a topmost portion 124e5. Topmost portion 124e5 can be wider than middle portion 124e4, which can be wider than bottommost portion 124e3. In some embodiments, bottommost portion 124e3 can have a width W1 equal to or greater than about 0.5 μm and topmost portion 124e5 can have a width W2 equal to or greater than about 1.2 times of width W1. In some embodiments, a height H3 of bottommost portion 124e3 can be greater than a height H4 of middle portion 124e4 and a height H5 of topmost portion 124e5. In some embodiments, height H5 can be equal to or greater than about 25% of total height H_{T} of embedded portion 124e*.

Referring to FIGS. 1A-1C, in some embodiments, capping layer 126 can include a Si layer or a Si-based layer (e.g., silicon nitride (SiN)). In some embodiments, capping layer 126 can include an element with a band gap different from the band gap of the element included in epitaxial structure 124A, which results in band discontinuity between epitaxial structure 124A and capping layer 126 (e.g., a difference between the minimum conduction band energy and/or the maximum valence band energy of epitaxial structure 124 and capping layer 126). In some embodiments, capping layer 126 can have thickness T1 of about 10 nm to about 15 nm. In some embodiments, doped regions 130 and 132 can be present in epitaxial structure 124A and in capping layer 126. In some embodiments, doped regions 130 and 132 may be absent in epitaxial structure 124A and in capping layer 126.

In some embodiments, contact structures 134 can be configured to electrically connect epitaxial structure 124A to first multi-level metallization layer 104 through via structures 136. Each of contact structures 134 can include a silicide layer 134A and a contact plug 134B. Silicide layers 134A are disposed on p- and n-type doped regions 130 and 132 and in capping layer 126. In some embodiments, silicide layers 134A can include nickel silicide (NiSi), tungsten silicide (WSi₂), titanium silicide (TiSi₂), cobalt silicide (CoSi₂), or a suitable metal silicide. Contact plugs 134B are disposed on silicide layers 134A and in ILD layer 114. In some embodiments, contact plugs 134B can include conductive materials, such as ruthenium (Ru), iridium (Ir), nickel (Ni), Osmium (Os), rhodium (Rh), aluminum (Al), molybdenum (Mo), tungsten (W), cobalt (Co), copper (Cu), and any suitable metallic material. Via structures 136 are disposed on contact plugs 134B and in passivation layer 112. In some embodiments, via structures 136 can include conductive materials, such as Ru, Co, Ni, Al, Mo, W, Ir, Os, Cu, Pt, and any other suitable metallic material.

Referring to FIG. 1A, isolation regions 102B can include isolation structures 140 having n-type doped regions 140A and p-type doped regions 140B that are configured to form PN junction based isolation structures. The isolation structures can be electrically connected to first multi-level metallization layer 104 and/or other circuits through contact structures 134 and via structures 136. Contact pad region 102C can include a pad structure 120 and one or more conductive bonding pads or solder bumps (not shown) on pad structure 120 through which electrical connections between BSI image sensor 102 and external circuit can be established. Pad structure 120 is an input/output (I/O) port of BSI image sensor 102 and includes a conductive layer that is electrically coupled to multi-level interconnect structure 104A.

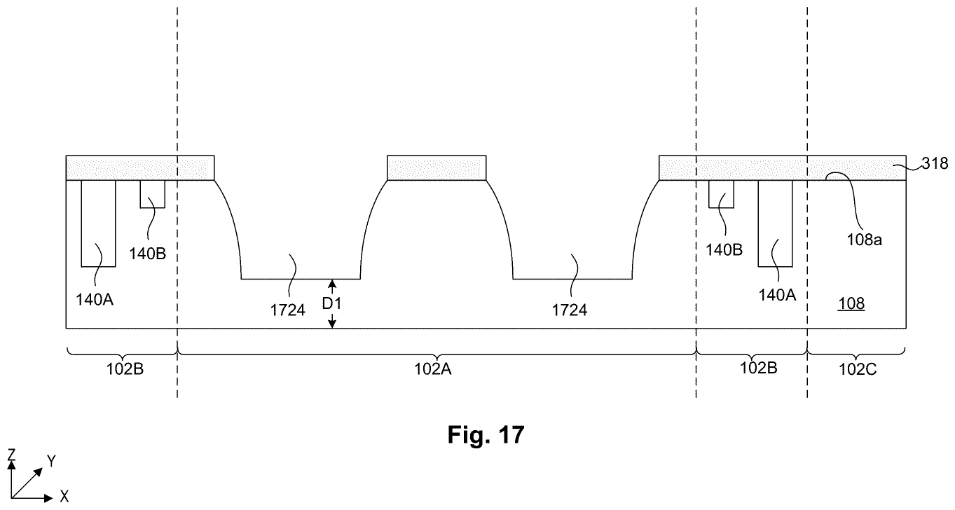

FIG. 1D illustrates another cross-sectional view of semiconductor device 100, according to some embodiments. FIG. 1E illustrates an enlarged cross-sectional view of a region 101 of FIG. 1D, according to some embodiments. The discussion of elements in FIGS. 1A-E with the same annotations applies to each other, unless mentioned otherwise. In some embodiments, pixel structure 122A can have epitaxial structure 124B, as shown in FIGS. 1D and 1E, instead of epitaxial structure 124e of FIGS. 1A and 1B or epitaxial structure 124e* of FIG. 1C. In some embodiments, epitaxial structure 124B can have a tapered structure with sidewalls having curved profiles. The tapered structure of epitaxial structure 124B can have a bottom surface 124Bb with a width W1 and a top surface 124Bt with a width W2, which is greater than width W1. In some embodiments, width W1 can be equal to or greater than about 0.5 μm and width W2 can be equal to or greater than about 1.2 times of width W1. In some embodiments, epitaxial structure 124B can extend to height H_{T} of about 100 nm to about 200 nm below front-side surface 108f of substrate 108 and back-side surface 124Bb of epitaxial structure 124B can be above back-side surface 108b of substrate 108 by distance D1 of about 75 nm to about 125 nm. Within these ranges of widths W1 and W2, height H_{T}, and distance D1, the tapered structure of epitaxial structure 124B can prevent or minimize the material of epitaxial structure 124B from laterally expanding over the edges of trenches 1724 (shown in FIG. 17) during high temperature processes, as described in detail below.

In some embodiments, top surface 124Bt of epitaxial structure 124B can have a surface portion 124Bt1 with a substantially planar profile and a surface portion 124Bt2 with a curved profile surrounding surface portion 124Bt1. In some embodiments, surface portion 124Bt1 can be substantially coplanar with front-side surface 108f of substrate 108 and surface portion 124Bt2 can extend above front-side surface 108f of substrate 108.

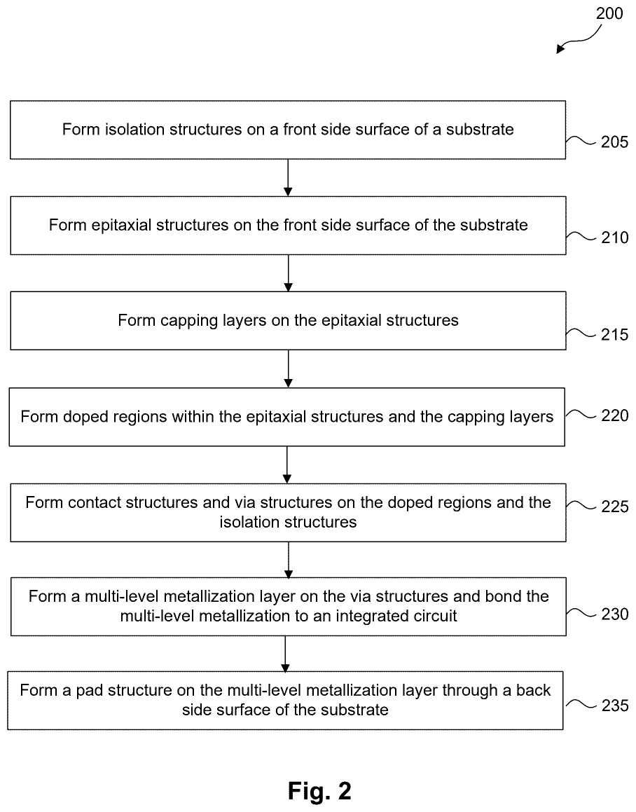

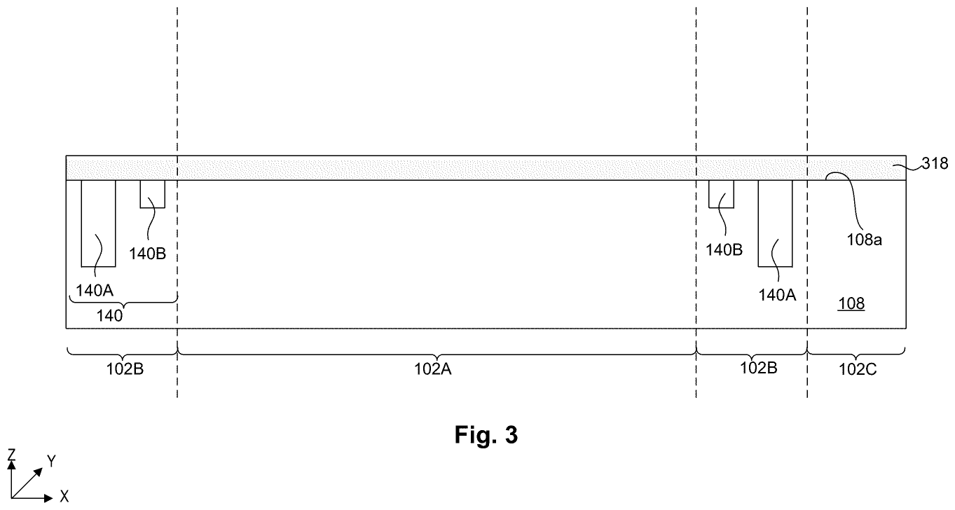

FIG. 2 is a flow diagram of an example method 200 for fabricating semiconductor device 100 with the cross-sectional view of FIG. 1A, according to some embodiments. For illustrative purposes, the operations illustrated in FIG. 2 will be described with reference to the example fabrication process for semiconductor device 100 as illustrated in FIGS. 3-15. FIGS. 3-15 are cross-sectional views of semiconductor device 100 at various stages of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. Elements in FIGS. 3-15 with the same annotations as elements in FIGS. 1A and 1B are described above.

In operation 205, isolation structures are formed on a front-side surface of a substrate. For example, as shown in FIG. 3, n-type doped regions 140A and p-type doped regions 140B of isolation structures 140 are formed on front-side surface 108a of substrate 108. N- and p-type doped regions 140A and 140B can be formed by ion implanting dopants into substrate 108 through front-side surface 108a. Following the formation of doped regions 140A and 140B, a dielectric layer 318 can be deposited on front-side surface 108a, as shown in FIG. 3. Dielectric layer 318 can include a material of dielectric layer 118. The formation of dielectric layer 318 can include using a CVD process, an ALD process, a thermal oxidation process, or a suitable deposition process for dielectric materials.

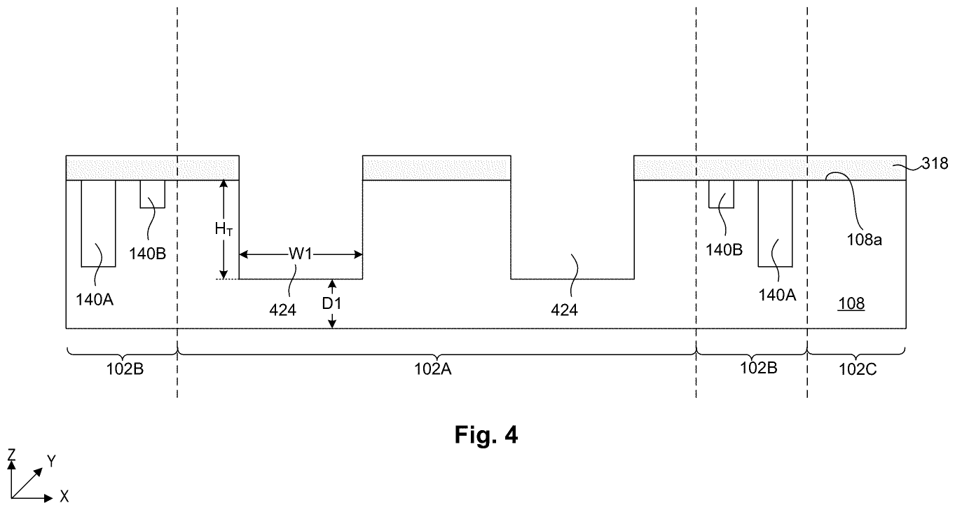

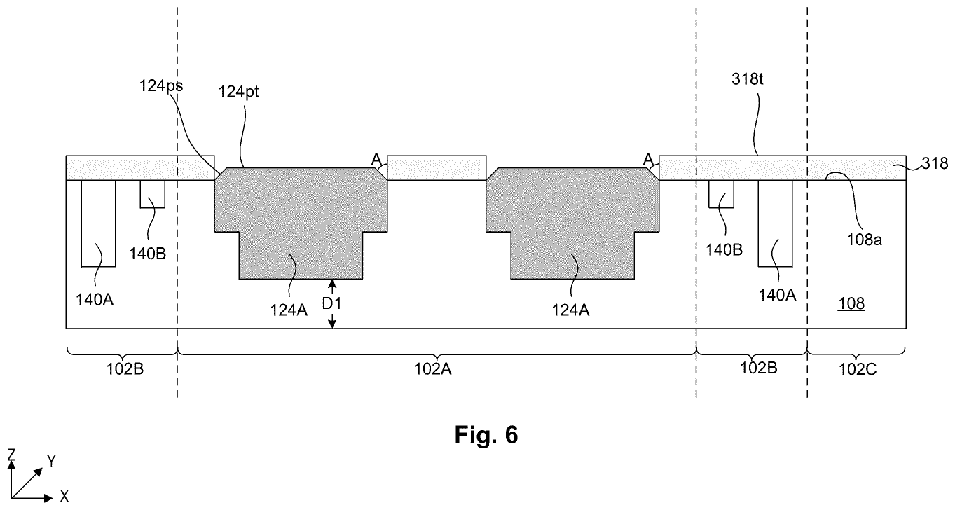

Referring to FIG. 2, in operation 210, epitaxial structures are formed on the front-side surface of the substrate. For example, as described with reference to FIGS. 4-6, epitaxial structures 124A can be formed at the same time on front-side surface 108a of substrate 108. The formation of epitaxial structures 124A can include sequential operations of (i) forming trenches 424 with vertical sidewall profiles at the same time in substrate 108 through dielectric layer 318, as shown in FIG. 4, (ii) modifying trenches 424 to form trenches 524 with stepped sidewall profiles, as shown in FIG. 5, and (iii) forming, at the same time, epitaxial structures 124A in trenches 524, as shown in FIG. 6.

In some embodiments, the formation of trenches 424 can include a dry etching process with etchants, such as chlorine-based gas, helium, fluorine-based gas, argon, and a combination thereof. In some embodiments, each of trenches 424 can be formed with a width W1 and a height H_{T} extending into substrate 108. In some embodiments, modifying trenches 424 to form trenches 524 can include etching exposed regions of substrate 108 and dielectric layer 318 in trenches 424 to increase width W1 of a top portion of trench 424 to width W2. As a result, trenches 524 can be formed with a bottom trench portion 524A having width W1 and a top trench portion 524 having width W2, which is greater than width W1. In some embodiments, width W1 can be equal to or greater than about 0.5 μm and width W2 can be equal to or greater than about 1.2 times of width W1. In some embodiments, bottom trench portion 524A can have a height H1 of about 175 nm to about 200 nm and top trench portion 524B can have a height H2 of about 50 nm to about 100 nm. In some embodiments, height H2 can be equal to or greater than about 25% of total height H_{T} of trench 524 in substrate 108 and can be smaller than height H1. The stepped structures of trenches 524 with the above-mentioned ranges of widths W1 and W2 and heights H1 and H2 can prevent or minimize the material of subsequently-formed epitaxial structures 124A from laterally expanding over the edges of trenches 524 and on dielectric layer 318 during subsequent high temperatures processes.

In some embodiments, instead of forming and modifying trenches 424 to form trenches 524, trenches 524 can be formed by forming top trench portions 524B prior to forming bottom trench portions 524A. In this case the formation of epitaxial structures 124A can include sequential operations of (i) forming top trench portions 524B with widths W2 and heights H2 by etching substrate 108 through dielectric layer 318 in the structure of FIG. 3, (ii) forming bottom trench portions 524A with width W1 and height H1 by etching substrate 108 through trenches 524B, and (iii) forming, at the same time, epitaxial structures 124A in trenches 524, as shown in FIG. 6.

In some embodiments, forming epitaxial structures 124A can include (i) epitaxially growing, at the same time, a layer of Si, SiGe, or a III-V element of the periodic table (not shown) in trenches 524, (ii) performing a chemical mechanical polishing (CMP) process (also referred to as “a surface treatment process”) on the layer of Si, SiGe, or a III-V element, (iii) etching the polished layer of Si, SiGe, or a III-V element to form epitaxial structures 124A with top surfaces 124pt lower than a top surface 318t of dielectric layer 318, as shown in FIG. 6, and (v) performing a cleaning process on the structure of FIG. 6. In some embodiments, between operations (i) and (ii) of forming epitaxial structures 124A, a photolithographic process can be performed to form a masking layer on dielectric layer 318. The photolithographic process can be followed by performing an etching process on the layer of Si, SiGe, or a III-V element in trenches 524 prior to performing the CMP process of operation (ii).

The epitaxial growth of layer of Si, SiGe, or a III-V element can include epitaxially growing monocrystalline or polycrystalline structures of Si, SiGe, or a III-V element of the periodic table. In some embodiments, the layer of Si, SiGe, or a III-V element can selectively grow within trenches 524 due to the presence of dielectric layer 318, which can have an amorphous structure. The amorphous dielectric layer 318 can prevent the epitaxial growth of layer of Si, SiGe, or a III-V element on regions covered by dielectric layer 318. In some embodiments, the selective growth of the layer of Si, SiGe, or III-V element can result in monocrystalline structures of Si, SiGe, or a III-V element of the periodic table. In some embodiments, the selective epitaxial growth of Ge in trenches 524 can be performed using a precursor gas of germane (GeH₄) at a flow rate of about 100 seem to about 5000 sccm, a carrier gas of hydrogen at a flow rate of about 1000 seem to about 20000 sccm, and an etching gas of HCl at a flow rate of about 50 seem to about 1000 sccm. In some embodiments, the selective epitaxial growth of Ge in trenches 524 can be performed at a temperature of about 300° C. to about 1000° C. and at a pressure of about 5 torr to about 50 torr.

The CMP process can include using a CMP slurry with a higher removal selectivity for the material of epitaxial structures 124A than for the material of dielectric layer 318. The term “removal selectivity” refers to the ratio of the removal rates of two different materials under the same removal conditions. In some embodiments, the CMP slurry can have a removal selectivity that is about 20 times to about 200 times greater for the material of epitaxial structures 124A than for the material of dielectric layer 318. The CMP slurry can include hydrogen peroxide, potassium peroxydisulfate, nitrogen-oxide-based compound, polyethylene glycol, abrasive particles, such as colloidal silica, fumed silica, aluminum oxide, and a combination thereof. In some embodiments, during the etching of the polished layer of Si, SiGe, or a III-V element, dielectric layer 318 can be protected by a masking layer (e.g., a photoresist layer), which can be formed in a photolithographic process.

The etching of the polished layer of Si, SiGe, or a III-V can include a wet etch process, a dry etch process, or a vapor etch process using halogen-based etchants. The etchants have a higher etch selectivity (e.g., about 20 to about 50 times higher) for the material of epitaxial structures 124A than the etch selectivity for the material of dielectric layer 318 and substrate 108. The cleaning process can include cleaning the structure of FIG. 6 to remove contaminants and/or residues from the CMP process and/or the etching process with an acid-based cleaning solution, such as diluted hydrofluoric acid (DHF) and/or hydrogen peroxide (H₂O₂).

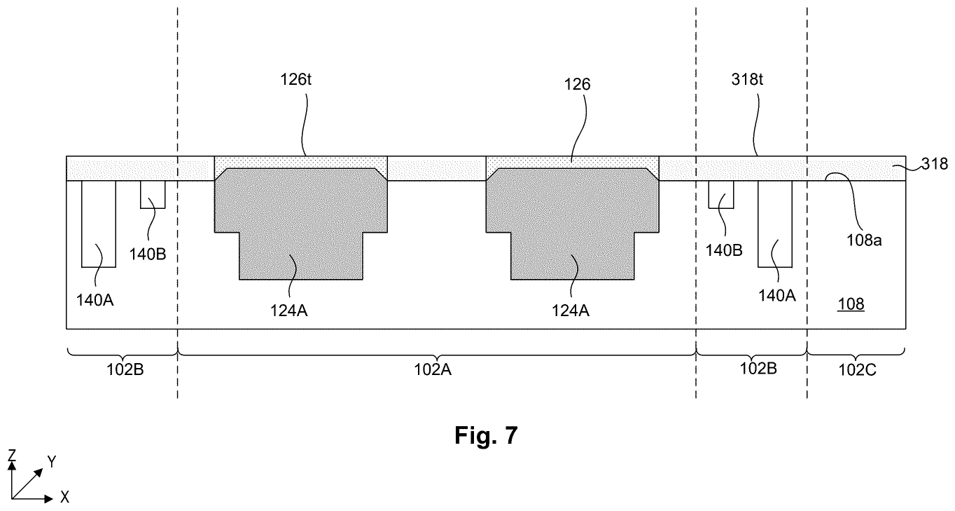

Referring to FIG. 2, in operation 215, capping layers are formed on the epitaxial structures. For example, as shown in FIG. 7, capping layers 126 can be formed on epitaxial structures 124A. In some embodiments, the formation of capping layers 126 can include epitaxially growing a Si, Ge, or SiGe layer on epitaxial structures 124A. In some embodiments, instead of epitaxially growing capping layers 126, the formation of capping layers 126 can include sequential operations of (i) depositing a Si, Ge, SiGe, or SiN layer (not shown) on the structure of FIG. 6, (ii) forming a patterned masking layer (not shown) on the Si, Ge, SiGe, or SiN layer to protect portions of the Si, Ge, SiGe, or SiN layer on epitaxial structures 124A, and (iii) selectively etching portions of the Si, Ge, SiGe, or SiN layer that are not protected by the patterned masking layer to form the structure of FIG. 7. The deposition of the Si, Ge, or SiGe layer can include using a silicon precursor (e.g., silane (SiH₄) or dichlorosilane (DCS)) and/or a germanium precursor (e.g., germane (GeH₄)) in a chemical vapor deposition (CVD) process or an atomic layer deposition (ALD) process. In some embodiments, capping layers 126 can be formed with top surfaces 126t of capping layers 126 substantially coplanar with top surface 318t of dielectric layer 318, as shown in FIG. 7

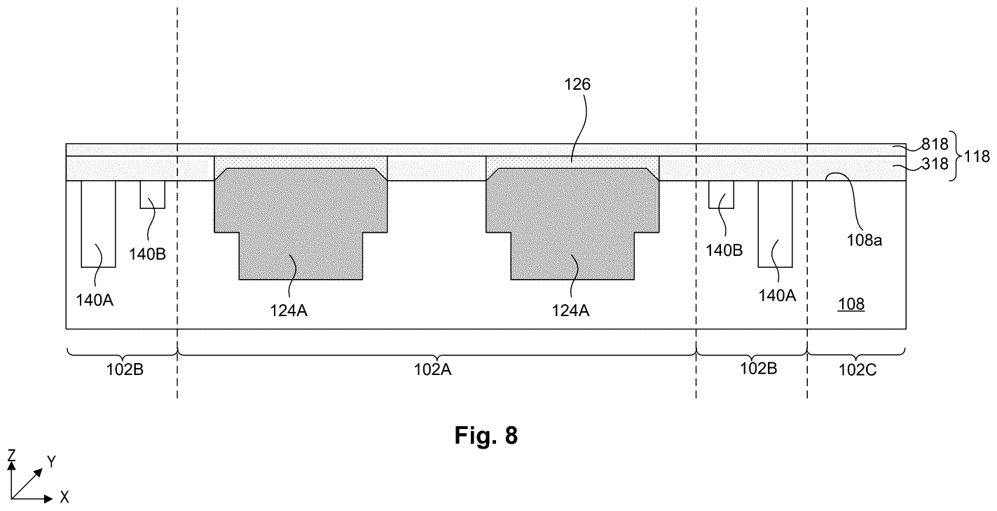

In some embodiments, following the formation of capping layers 126, a dielectric layer 818 with material similar to the material of dielectric layer 318 can be deposited on the structure of FIG. 7 to form the structure of FIG. 8. The formation of dielectric layer 818 can include using a CVD process, an ALD process, or a thermal oxidation process.

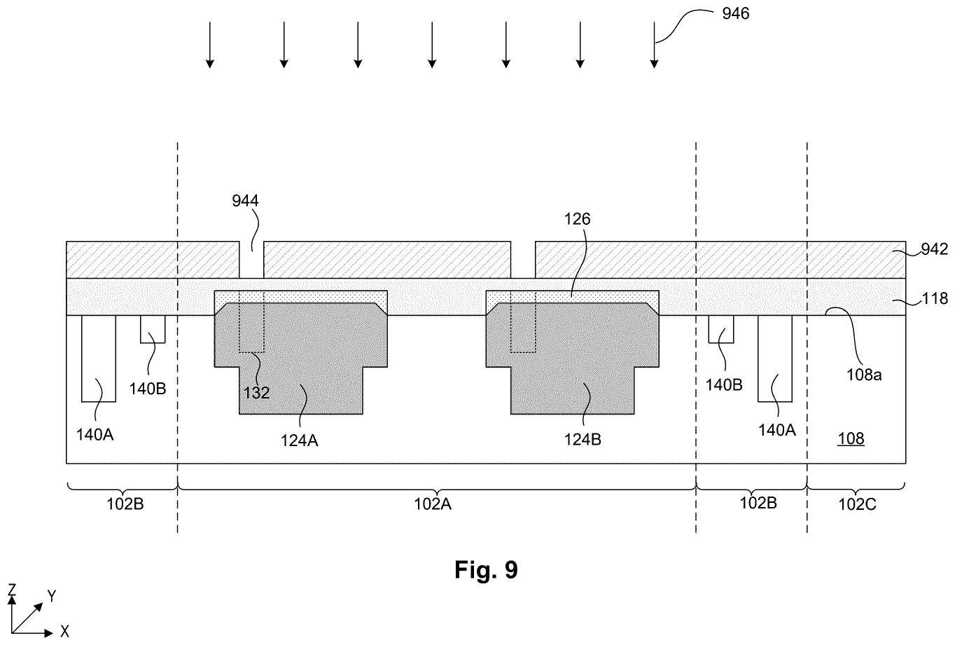

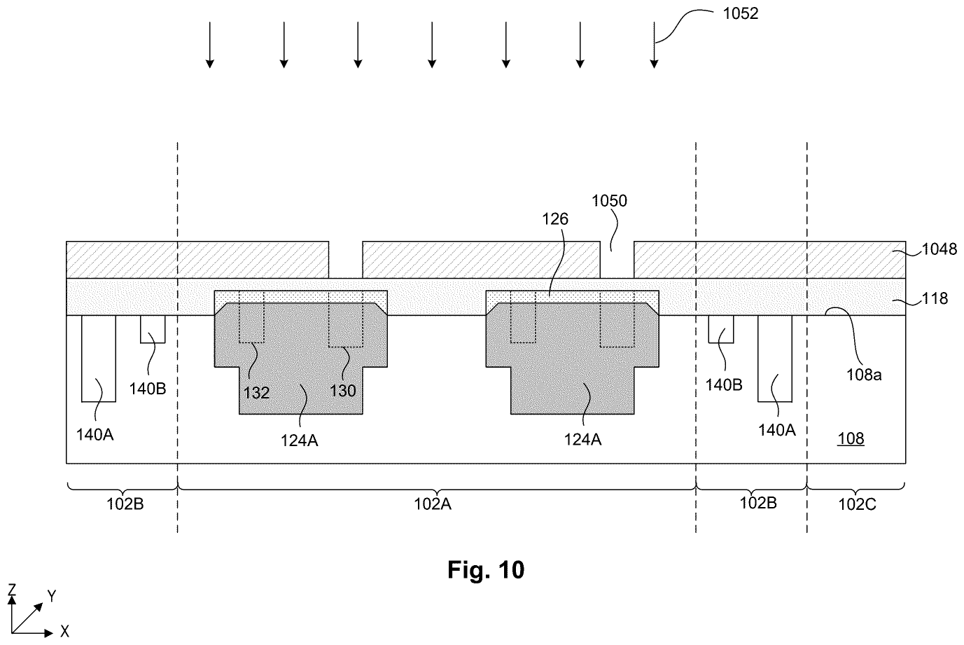

Referring to FIG. 2, in operation 220, doped regions are formed in the epitaxial structures and the capping layers. For example, as described with reference to FIGS. 9 and 10, p-type doped regions 130 and n-type doped regions 132 can be formed in capping layers 126 and epitaxial structures 124A. The formation of p-type doped regions 130 and n-type doped regions 132 can include sequential operations of (i) forming a patterned masking layer 942 with openings 944, as shown in FIG. 9, (ii) ion implanting n-type dopants 946 into capping layers 126 and epitaxial structures 124A through openings 944 to form doped regions 132, as shown in FIG. 9, (iii) removing patterned layer 942 (not shown), (iv) forming a patterned masking layer 1048 with openings 1050, as shown in FIG. 10, (v) ion implanting p-type dopants 1052 into capping layers 126 and epitaxial structures 124A through openings 1050 to form p-type doped regions 130, as shown in FIG. 10, and (vii) performing an annealing process on the structure of FIG. 10 after removing patterned layer 1048 to activate the dopants in doped regions 130 and 132.

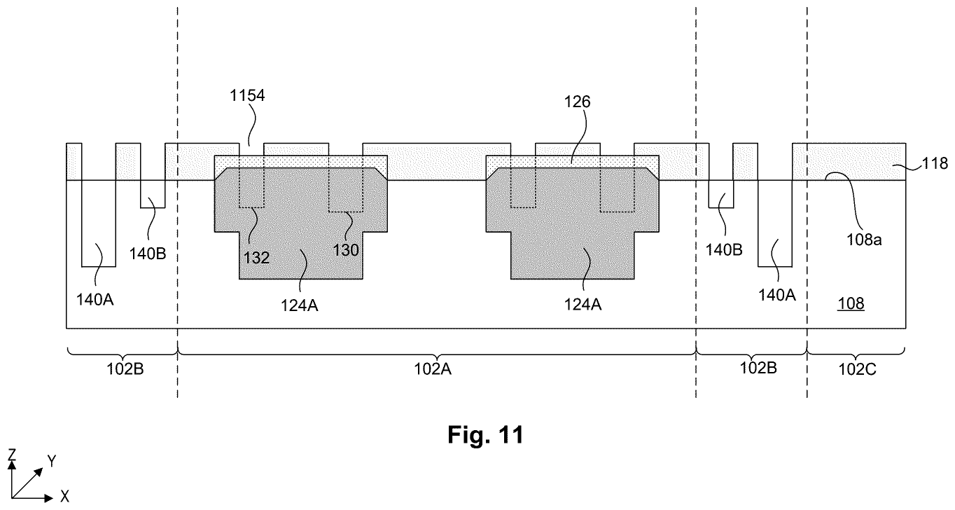

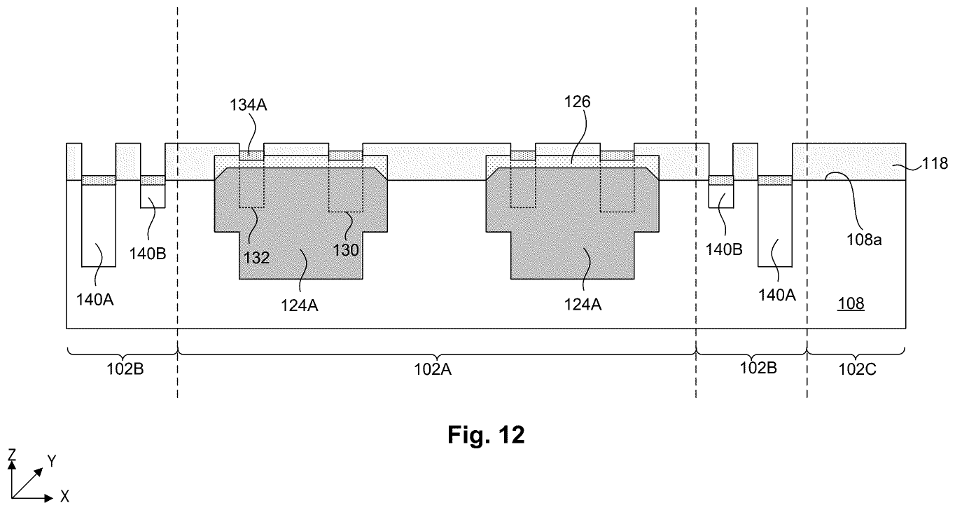

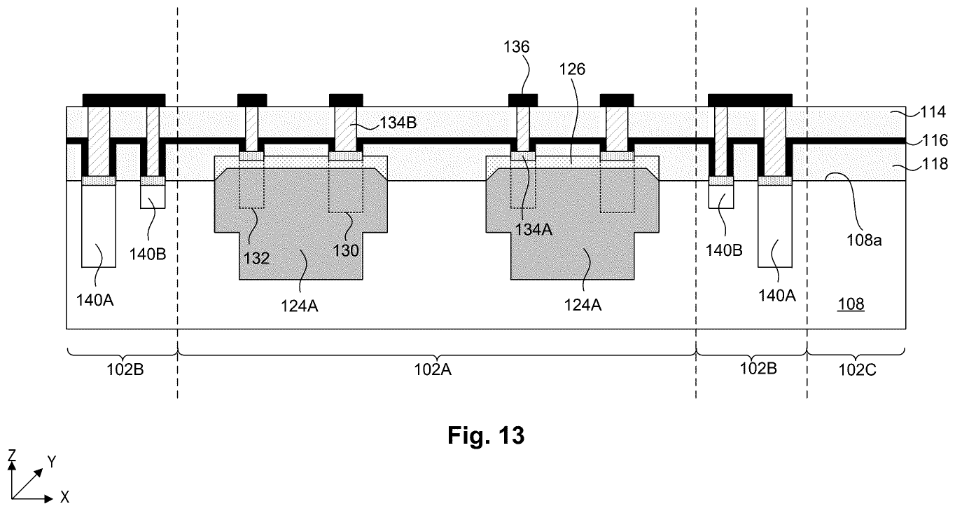

Referring to FIG. 2, in operation 225, contact structures and via structures are formed on the doped regions and the isolation structures. For example, as described with reference to FIGS. 11-13, contact structures 134 with silicide layers 134A and contact plugs 134B are formed on doped regions 130 and 132 and 140A and 140B, and via structures 136 are formed on contact structures 134. The formation of contact structures 134 can include sequential operations of (i) forming silicide openings 1154 on doped regions 130 and 132 and 140A and 140B, as shown in FIG. 11, (ii) forming silicide layers 134A on doped regions 130 and 132 and 140A and 140B, as shown FIG. 12, (iii) depositing ESL 116 on silicide layers 134A and dielectric layer 118, as shown in FIG. 13, (iv) depositing ILD layer 114 on ESL 116, as shown in FIG. 13, (v) forming contact openings (not shown) in ILD layer 114 and ESL 116 to expose portions of silicide layers 134A, and (vi), forming contact plugs 134B in contact openings, as shown in FIG. 13.

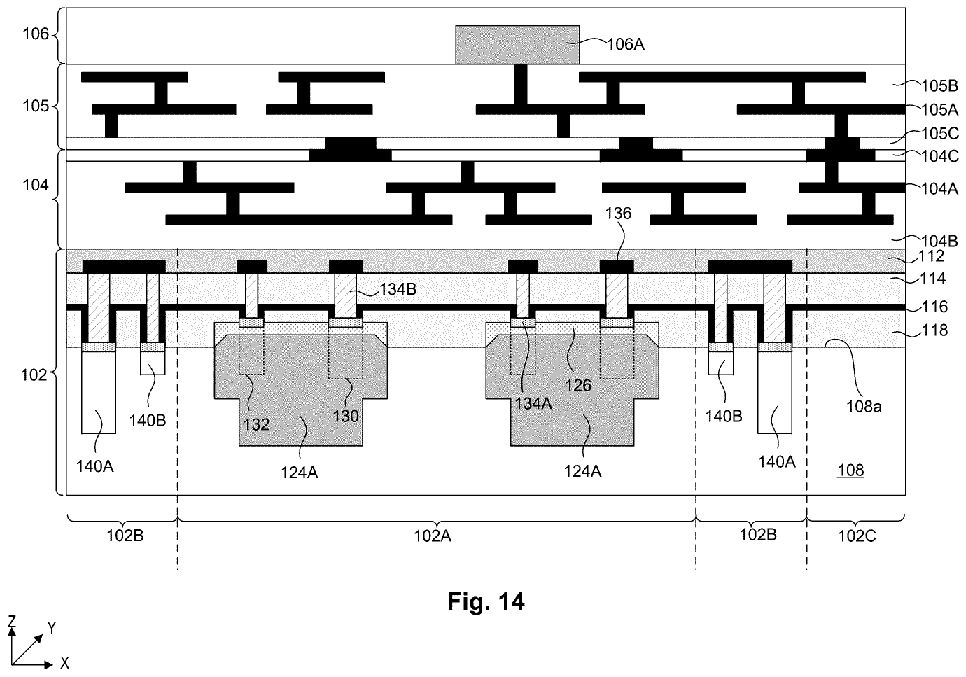

The formation of silicide layers 134A can include sequential operations of (i) depositing a metal layer (not shown) on the structure of FIG. 11, (ii) performing an annealing process on the structure with the metal layer, and (iii) removing the non-reacted portions of the metal layer on dielectric layer 118 to form the structure of FIG. 12. The formation of via structures 136 can include depositing a metal layer (not shown) on the structure after the formation of contact plugs 134B and patterning the deposited metal layer to form the structure of FIG. 13. Following the formation of via structures 136, passivation layer 112 can be deposited on ILD layer 114 and via structures 136, as shown in FIG. 14.

Referring to FIG. 2, in operation 230, a multi-level metallization layer is formed on the via structures and bonded to an integrated circuit. For example, as shown in FIG. 14, first multi-level metallization layer 104 with multi-level interconnect structure 104A embedded in IMD layer 104B is formed on via structures 136 and passivation layer 112. The formation of multi-level metallization layer 104 can be followed by bonding second multi-level metallization layer 105 and ASIC 106 to multi-level metallization layer 104, as shown in FIG. 14.

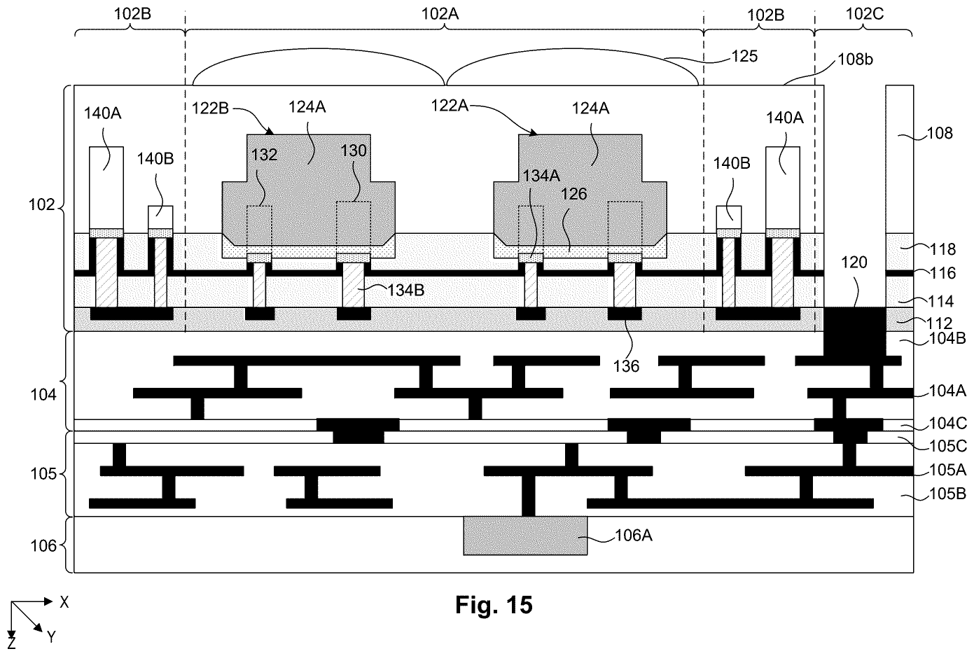

Referring to FIG. 2, in operation 235, a pad structure is formed on the multi-level metallization layer through a back-side surface of the substrate. For example, as shown in FIG. 15, pad structure 120 is formed on multi-level interconnect structure 104A through back-side surface 108b. The formation of pad structure 120 can include sequential operations of (i) forming a pad opening (not shown) in substrate 108, dielectric layer 118, ESL 116, ILD layer 114, passivation layer 112, and a portion of IMD layer 104B, (ii) depositing a conductive layer (not shown) in the pad opening, and (iii) patterning and etching the conductive layer to form pad structure 120 in pad opening, as shown in FIG. 15. Following the formation of pad structure 120, an array of micro-lens 125 can be formed on back-side surface 108b, as shown in FIG. 15.

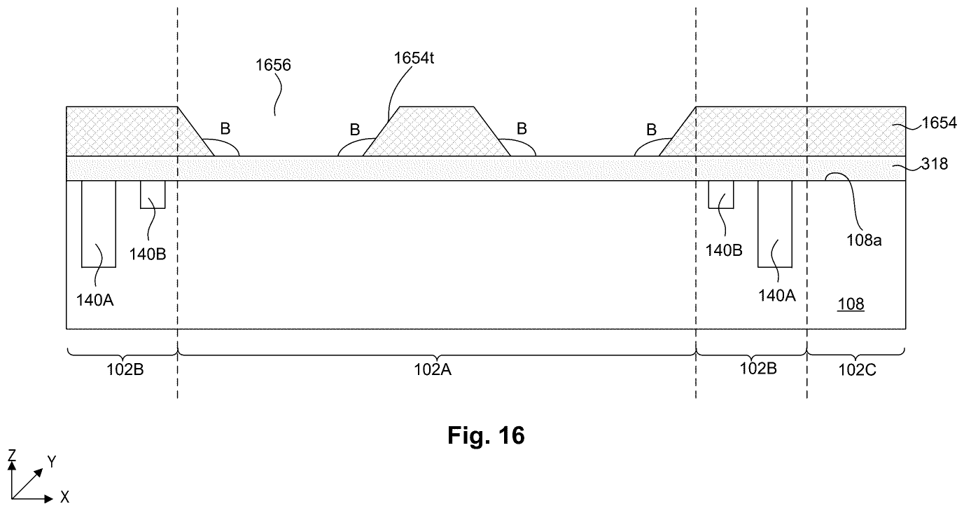

In some embodiments, operations similar to operations 205-235 of method 200 of FIG. 2 can be used to form semiconductor device 100 with the cross-sectional view of FIG. 1D, except in operation 210 of method 200, epitaxial structures 124B of semiconductor device 100 of FIG. 1D are formed as described with reference to FIGS. 16-18, instead of the operations described with reference to FIGS. 4-6 to form epitaxial structures 124A of semiconductor device 100 of FIG. 1A.

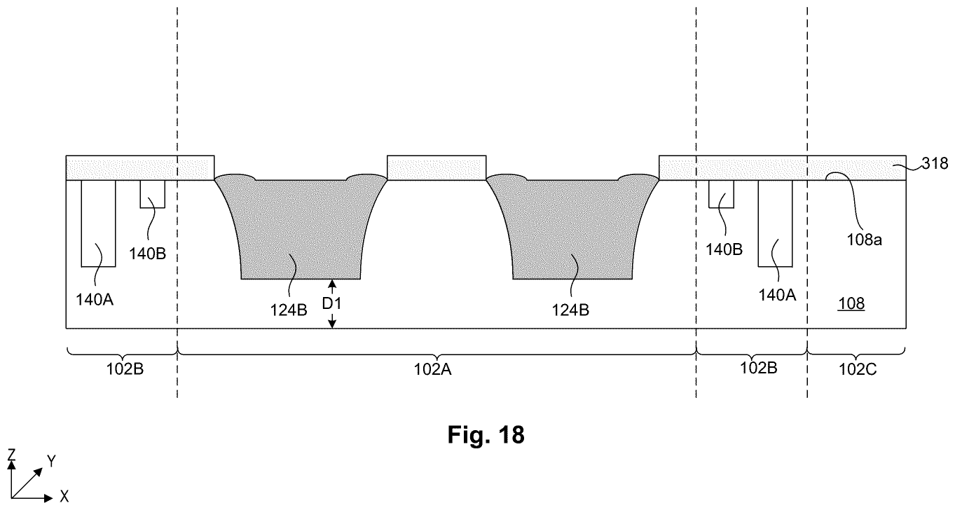

In some embodiments, the formation of epitaxial structures 124B can include sequential operations of (i) forming a patterned masking layer 1654 on dielectric layer 318, as shown in FIG. 16, (ii) forming trenches 1724 with tapered structures and curved sidewall profiles in substrate 108 through openings 1656, as shown in FIG. 17, (iii) removing patterned masking layer 1654, as shown in FIG. 17, and (iv) forming epitaxial structures 124B in trenches 1724, as shown in FIG. 18. In some embodiments, sidewalls 1654t of patterned masking layer 1654 facing openings 1656 can be formed with a sloped profile. The sloped profile of sidewalls 1654t can control the etch profile of trenches 1724. In some embodiments, each sidewall 1654t can form an angle B of about 135 degrees to about 140 degrees with respect to top surface of dielectric layer 318. Within this range of angle B, the sloped profile of sidewalls 1654t can control the etch profile of trenches 1724 to form trenches 1724 with tapered cross-sectional profiles and curved sidewall profiles, as shown in FIG. 17. In some embodiments, the process for forming epitaxial structures 124B in trenches 1724 can be similar to that described with reference to FIG. 6 for the formation of epitaxial structures 124A in trenches 524.

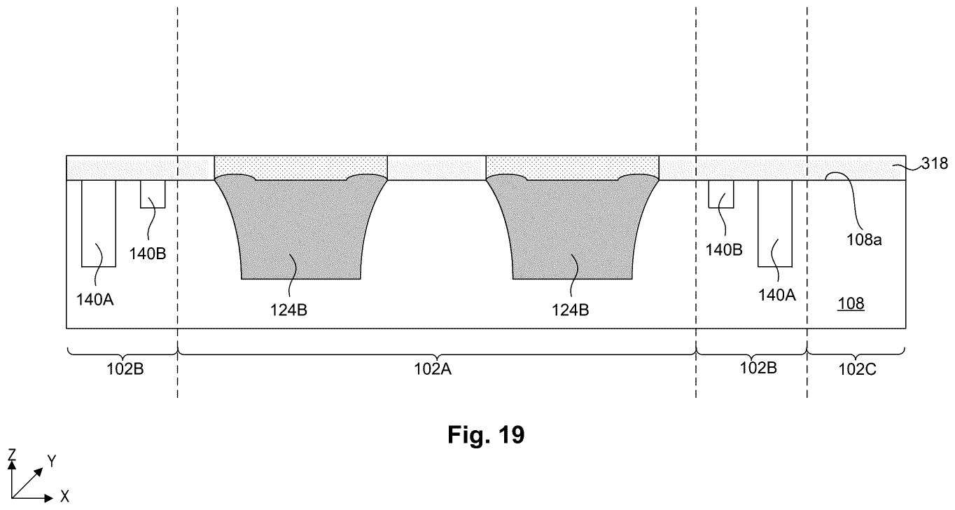

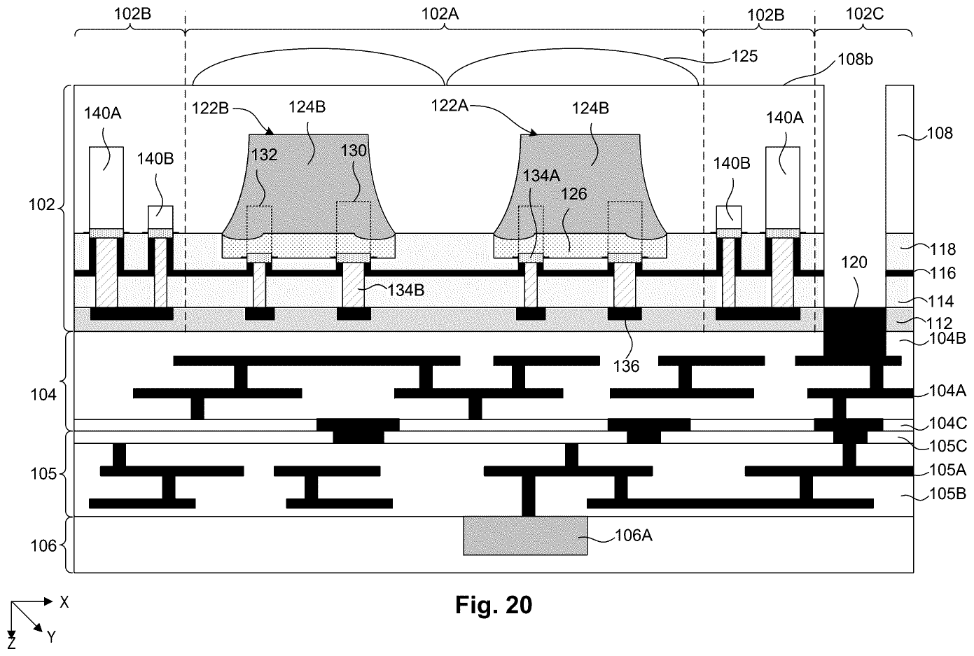

The operation of forming epitaxial structures 124B in trenches 1724 can be followed by operation 215 of method 200, as described with reference to FIG. 7, to form capping layers 126 on epitaxial structures 124B, as shown in FIG. 19. The formation of capping layers 126 can be followed by operations similar to operations 220-235 of method 200, as described with reference to FIGS. 8-15, to form the structure of FIG. 20.

The present disclosure provides example structures and methods for improving the surface uniformity of the epitaxial structures (e.g., epitaxial structures 124A and 124B) in a BSI image sensor (e.g., BSI image sensor 102) and as a result, improving the interfaces between the epitaxial structures and the Si-based capping layers (e.g., Si-based capping layers 126) and/or between the epitaxial structures and the sidewalls of the trenches (e.g., trenches 524 and 1724). In some embodiments, the epitaxial structures can be formed in trenches with sidewalls having stepped profiles or having curved profiles. Such structures of the trenches can prevent or minimize the materials of the epitaxial structures from laterally expanding over the edges of the trenches during high temperatures processes.

In some embodiments, a semiconductor device includes a substrate, a pixel region with a pixel structure, an isolation region with an isolation structure disposed adjacent to the pixel region, and a contact pad region with a pad structure disposed adjacent to the isolation region. The pixel structure includes an epitaxial structure, which includes an embedded portion with a stepped structure disposed in the substrate and a protruding portion extending above a top surface of the substrate. The pixel structure further includes a capping layer disposed on the protruding portion.

In some embodiments, a semiconductor device includes a substrate, a pixel structure, and an isolation structure. The pixel structure includes an epitaxial structure disposed in the substrate and a silicon-based capping layer disposed on the epitaxial structure. The epitaxial structure includes a bottom surface with a first width and a top surface with a second width that is greater than the first width. The isolation structure includes a doped region disposed adjacent to the pixel structure.

In some embodiments, a method includes forming, in a substrate, a trench with a stepped cross-sectional profile, forming an epitaxial structure in the trench, forming a silicon-based capping layer on the epitaxial structure, forming a doped region in the epitaxial structure and the capping layer, forming a silicide layer on the doped region, forming an etch stop layer on the silicide layer, and forming conductive plugs on the silicide layer through the etch stop layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a pixel structure, comprising:
a first pixel portion disposed in the substrate and having sidewalls with stepped profiles,
a second pixel portion protruding above a top surface of the substrate and having sidewalls with sloped profiles, and
a capping layer disposed on the second pixel portion; and
an isolation structure disposed adjacent to the pixel structure.

2. The semiconductor device of claim 1, wherein the sidewalls comprise stepped profiles with a plurality of step levels.

3. The semiconductor device of claim 1, wherein materials of the first and second pixel portions are different from a material of the capping layer.

4. The semiconductor device of claim 1, wherein the first pixel portion comprises:
a bottom portion with a first width; and
a top portion with a second width that is greater than the first width.

5. The semiconductor device of claim 1, wherein the first pixel portion comprises:
a bottom portion with a first width; and
a top portion with a second width that is about 1.2 times of the first width.

6. The semiconductor device of claim 1, wherein the first pixel portion comprises:
a bottom portion with a first height; and
a top portion with a second height that is less than the first height.

7. The semiconductor device of claim 1, wherein the first pixel portion comprises:
a bottom portion with a first height;
a middle portion with a second height; and
a top portion with a third height,
wherein the first height is greater than the second and third heights.

8. The semiconductor device of claim 1, wherein the first pixel portion comprises:
a bottom portion with a first height;
a middle portion with a second height; and
a top portion with a third height that is about 25% of a sum of the first, second, and third heights.

9. The semiconductor device of claim 1, wherein each of the sidewalls of the second pixel portion forms an angle of about 5 degrees or less with a sidewall of the capping layer.

10. The semiconductor device of claim 1, wherein the pixel structure further comprises a doped region disposed in the capping layer and the first and second pixel portions.

11. A semiconductor device, comprising:
a substrate;
a pixel structure comprising:
a first pixel portion, disposed in the substrate, comprising:
a bottom pixel portion with a first height,
a middle pixel portion with a second height, and
a top pixel portion with a third height, wherein the first height is greater than the second and third heights; and
a second pixel portion protruding above a top surface of the substrate; and
an isolation structure comprising a doped region disposed adjacent to the pixel structure.

12. The semiconductor device of claim 11, wherein:
the bottom pixel portion has a first width,
the middle pixel portion has a second width greater than the first width, and
the top pixel portion has a third width greater than the second width.

13. The semiconductor device of claim 11, wherein the second pixel portion comprises a tapered structure.

14. The semiconductor device of claim 11, wherein materials of the first and second pixel portions are different from a material of the substrate.

15. The semiconductor device of claim 11, wherein the third height is about 25% of a sum of the first, second, and third heights.

16. The semiconductor device of claim 11, wherein the pixel structure further comprises a capping layer disposed on the second pixel portion and comprising a material different from a material of a material of the second pixel portion.

17. A method, comprising:
etching a substrate to form a trench with sidewalls having curved profiles;
epitaxially growing, in the trench, a semiconductor layer with a first surface portion protruding above the substrate and a second surface portion substantially coplanar with a top surface of the substrate;
forming a capping layer on the semiconductor layer;
performing a doping process on the semiconductor layer and the capping layer; and
forming a contact structure on the capping layer.

18. The method of claim 17, wherein epitaxially growing the semiconductor layer comprises epitaxially growing a silicon-based or a germanium-based layer.

19. The method of claim 17, wherein etching the substrate comprises forming a patterned masking layer with sloped sidewalls on the substrate.

20. The method of claim 17, further comprising forming an isolation structure in the substrate prior to etching the substrate.
